(19) United States
(12) Patent Application Publication
(10) Pub. No.: US 2014/0253183 A1
(43) Pub. Date: Sep. 11, 2014

(54) FIELD EFFECT TRANSISTOR DEVICE

(71) Applicant: Kabushiki Kaisha Toshiba, Minato-ku (JP)

(72) Inventor: Stuart N. HOLMES, Cambridge (GB)

(73) Assignee: Kabushiki Kaisha Toshiba, Minato-ku (JP)

(21) Appl. No.: 14/198,987

(22) Filed: Mar. 6, 2014

(30) Foreign Application Priority Data
Mar. 6, 2013 (GB) 1304048.0

(51) Int. Cl. H01L 29/24; H01L 29/778; H03K 3/01; H01L 29/66

(52) U.S. Cl. CPC H01L 29/24; H01L 29/66431; H01L 29/778; H03K 3/01
USPC 327/109; 257/43; 438/104

(57) ABSTRACT

A semi-metallic structure, comprising an LaAlO₃—SrTiO₃ heterostructure (19), said LaAlO₃—SrTiO₃ heterostructure comprising a two-dimensional hole gas (21) and a two-dimensional electron gas (23).

### FIELD

Embodiments of the present invention are concerned with the field of semimetals and their use in electronic devices.

### BACKGROUND

Field effect transistor (FET) devices use an electric field to modulate the conductivity of a conduction channel. Metal-oxide-semiconductor field-effect transistors (MOSFETs) are currently the most common type of transistor used in digital and analogue circuits.

Complementary metal-oxide-semiconductor (CMOS) devices employ complementary pairs of MOSFETs as logic gates. Logic devices employing CMOS schemes are widely used in the electronics industry.

There is a continuing need to improve the efficiency and reduce the size of CMOS devices.

### BRIEF DESCRIPTION OF THE DRAWINGS

Embodiments will now be described with reference to the following figures:

FIG. 1 is a schematic of a structure according to an embodiment;

FIG. 2 is a schematic of the band structure of a structure according to an embodiment;

FIG. 3(a) is an electronic device according to an embodiment in an “off state” configuration;

FIG. 3(b) is an electronic device according to an embodiment in an “on state” N-type configuration;

FIG. 3(c) is an electronic device according to an embodiment in an “on state” P-type configuration;

FIG. 4 is an electronic device according to an embodiment;

FIG. 5(a) shows the persistent photoconductivity in three devices according to an embodiment;

FIG. 5(b) shows the magnetoresistance in two devices according to an embodiment;

FIG. 6(a) shows Shubnikov-de Haas oscillations of the magnetoresistance of a device according to an embodiment;

FIG. 6(b) shows a fit of Landau level harmonic index against 1/B for the Shubnikov-de Haas minima shown in FIG. 6(a);

FIG. 7 shows magnetic field modulation measurements for a device according to an embodiment;

FIG. 8(a) shows hole density enhancement for negative gate bias for a device according to an embodiment;

FIG. 8(b) shows electron density depletion with negative gate bias for a device according to an embodiment;

FIGS. 8(c) and (d) show changes in resistivity with gate bias for two devices according to an embodiment; and

FIG. 9 shows Hall resistance measurements for a device according to an embodiment.

### DETAILED DESCRIPTION OF THE DRAWINGS

In an embodiment, a semi-metallic structure is provided, said structure comprising an LaAlO₃—SrTiO₃ heterostructure, said LaAlO₃—SrTiO₃ heterostructure comprising a two-dimensional hole gas and a two-dimensional electron gas.

The structure may exhibit persistent photoconductivity following illumination with a red or infrared illumination source. The structure may exhibit persistent photoconductivity following illumination with a red or infrared illumination source at temperatures below −243° C. The structure may exhibit persistent photoconductivity following illumination with a red light emitting diode. The structure may exhibit persistent photoconductivity following illumination with a light emitting diode with a peak wavelength of 630 nm.

The LaAlO₃—SrTiO₃ heterostructure may comprise an SrTiO₃ substrate and an LaAlO₃ surface layer. The SrTiO₃ substrate and LaAlO₃ surface layer may have perovskite structures. The LaAlO₃ surface layer may comprise alternating layers of (LaO)⁺ and (AlO₂)⁻. The LaAlO₃ surface layer may comprise alternating overlying layers of (LaO)⁺ and (AlO₂)⁻. The alternating layers of (LaO)⁺ and (AlO₂)⁻ may overlie each other in the [001] direction. The SrTiO₃ substrate may comprise alternating layers of TiO₂ and SrO. The SrTiO₃ substrate may comprise alternating overlying layers of TiO₂ and SrO. The alternating layers of TiO₂ and SrO may overlie each other in the [001] direction. The LaAlO₃ surface layer comprises a surface. The LaAlO₃ surface layer may be terminated at the surface by a layer of AlO₂⁻.

The LaAlO₃—SrTiO₃ heterostructure comprises an interface. The interface may comprise a layer of (LaO)⁺ adjacent to a layer of TiO₂. The SrTiO₃ substrate may be terminated at the interface by a layer of TiO₂. The LaAlO₃ layer may be terminated at the interface by a layer of (LaO)⁺. The electron gas may be located at the interface. The hole gas may be located at the surface. The thickness of the LaAlO₃ surface layer may be between 3 and 10 unit cells inclusive. The thickness of the LaAlO₃ surface layer between the surface and the LaAlO₃/SrTiO₃ interface may be 10 unit cells. The thickness of the SrTiO₃ substrate may be up to 1 mm. The thickness of the SrTiO₃ substrate layer may be between 500 microns and 1 mm.

In another embodiment, an electronic device is provided. The electronic device comprises a semi-metallic structure, said structure comprising an LaAlO₃—SrTiO₃ heterostructure, said LaAlO₃—SrTiO₃ heterostructure comprising a two-dimensional hole gas and a two-dimensional electron gas. The electronic device may further comprise a first back-gate electrode on a surface of said SrTiO₃ substrate; a first source electrical contact; and a first drain electrical contact. The first source electrical contact and the first drain electrical contact may be in ohmic contact with both the two-dimensional hole gas and the two-dimensional electron gas. The device may comprise a voltage source configured to apply a bias voltage between the back-gate electrical contact and ground. The device may comprise a voltage source configured to apply a bias voltage between the first source electrical contact and the back-gate electrode. The device may comprise a voltage source configured to apply a voltage bias between the source electrical contact and the drain electrical contact. The hole density of the two-dimensional hole gas may increase and the electron density of said two-dimension electron gas may decrease upon application of a negative bias voltage to the back-gate electrode relative to the source electrical contact. The hole density of the two-dimensional hole gas may increase and the electron density of said two-dimension electron gas may decrease upon application of a negative bias voltage to the backgate.

The electronic device may further comprise a front gate electrode. The front gate electrode may be on the surface of the LaAlO₃ surface layer. The front gate electrode may comprise MgO, Al₂O₃ or SrTiO₃. The device may comprise a voltage source configured to apply a bias voltage between the front gate electrode and the source electrical contact. The density of holes in the hole gas may be modulated by modulating the bias voltage applied to the front gate electrode relative to the source electrical contact. The density of holes in the hole gas may decrease upon application of a positive bias voltage to front gate electrode relative to the source electrical contact.

In yet another embodiment, a method for fabricating a semi-metal structure is provided, wherein said semi-metallic structure comprises an LaAlO₃—SrTiO₃ heterostructure comprising a two-dimensional hole gas and a two-dimensional electron gas. The fabrication method comprises: depositing LaAlO₃ on a TiO₂ terminated SrTiO₃ substrate, wherein said depositing is performed under an oxygen pressure of at least 10⁻³ mbar and at a temperature of at least 800° C.; heating said structure to a temperature of at least 800° C., and cooling said structure to ambient temperature, wherein said heating and cooling of said structure are performed while exposing said structure to an oxygen pressure of greater than 0.1 mbar; and illuminating said structure using a red or infrared illumination source at temperatures less than −243° C. The illuminating may be done using a red light illuminating source. The illuminating may be done using an LED with a peak wavelength of 630 nm.

The fabrication method may further comprise forming a back-gate electrode on a first surface of said heterostructure; forming a source electrical contact such that said source electrical contact is in ohmic contact with both said two-dimensional hole gas and said two-dimensional electron gas; and forming a drain electrical contact such that said drain electrical contact is in ohmic contact with both said two-dimensional hole gas and said two-dimensional electron gas. The fabrication method may also comprise forming a front-gate electrode on a second surface of said heterostructure. The fabrication method may comprise depositing single atomic layers of LaAlO₃. The fabrication method may comprise pulsed laser deposition growth of LaAlO₃. The pulsed laser deposition growth may be epitaxial.

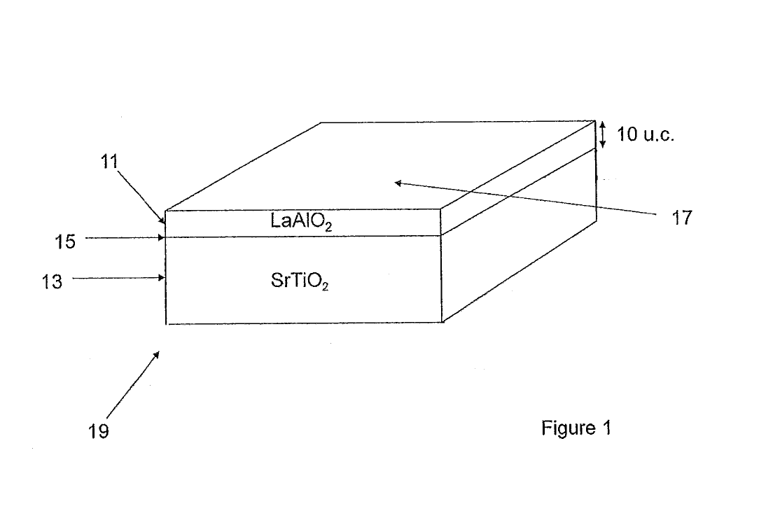

FIG. 1 shows a schematic of a structure 19 according to an embodiment. The structure comprises a substrate 13 of SrTiO₃, overlying which is positioned a layer 11 of LaAlO₃. The layer 11 of LaAlO₃ interfaces directly with the SrTiO₃ substrate 13 such that there exists an interface 15 between them. The layer 11 of LaAlO₃ comprises a surface 17. In an embodiment, the thickness between the interface 15 and the surface 17 of the layer 11 of LaAlO₃ is 3 to 10 unit cells. In an embodiment, the thickness of the SrTiO₃ substrate 13 is 500 μm to 1 mm.

The SrTiO₃ substrate and LaAlO₃ layer of the structure shown in FIG. 1 are perovskite structures. Perovskite structures are structures with the general formula ABX₃ having the crystal structure of CaTiO₃. The cubic unit cell of this crystal structure comprises cations “A” located at corner positions (0,0,0); smaller cations “B” at body centred positions (1/2, 1/2, 1/2); and anions “X” at face centred positions (1/2, 1/2, 0). The structure of the perovskite unit cell gives rise to a layered crystal structure. For example, in the [001] direction, LaAlO₃ comprises alternating overlying layers of (AlO₂)⁻ and (LaO)⁺. Similarly, in the [001] direction, SrTiO₃ comprises alternating overlying layers of TiO₂ and SrO.

In an embodiment, the surface 17 of structure 19 comprises a layer of (AlO₂)⁻. Equivalently, the LaAlO₃ layer 11 is terminated at the surface 17 by a layer of (AlO₂)⁻. In another embodiment, the interface 15 comprises a layer of (LaO)+ overlying a layer of TiO₂. Equivalently, the LaAlO₃ layer 11 is terminated at the interface 15 by a layer of (LaO)⁺ and the SrTiO₃ substrate 13 is terminated at the interface by a layer of TiO₂. The layer of (LaO)⁺ interfaces directly with the layer of TiO₂.

Structures, such as that shown in FIG. 1, comprising more than one crystalline material with a perovskite structure, are known as perovskite heterostrucutres. At the interface between two crystalline materials (heterointerface), a layer belonging to one of the materials is overlying a layer belonging to the other. Differences in the electrical properties of the two materials can give rise to changes in band structure near the interface and alter the electrical properties of the bulk material.

In an embodiment, the structure of FIG. 1 is characterised in that it is insulating in the dark at low temperatures but becomes conducting upon illumination with a red or infrared illumination source, exhibiting a strong persistent photoconductivity effect with below band gap excitation. In a further embodiment, the structure comprises both a high-mobility electron gas at the heterointerface 15 and a high mobility hole gas at the (AlO₂⁻) terminated surface 17 of the LaAlO₃ layer 11. In yet a further embodiment, due to the close spacing between the electron and hole gases, the semimetallic system is unstable towards exciton formation leading to Bose-Einstein condensation. Thus, the structure has an excitonic insulating ground state. However, the high mobility two-dimensional hole gas, in coexistence with an electron gas at the heterointerface, is stabilized by illumination with a red or infrared light emitting diode. In this embodiment, the LaAlO₃ surface layer can then sustain the large built-in electric fields required (˜1V/nm), to form a stable electron-hole gas and the structure exhibits spatially separated electron-hole bilayer behaviour in this excited state.

In an embodiment, in order to excite the structure 19 from its excitonic insulating ground state to its excited bilayer (semi-metal) state, structure 19 is illuminated with a red or infrared light emitting diode. In another embodiment, the structure 19 is illuminated with a red light emitting diode. In a further embodiment the structure 19 is illuminated with a red light emitting diode with a peak wavelength of 630 nm.

In the structures according to the above described embodiments, the hole mobility at the surface of the heteorostructure is high enough that a spin-split band structure can be observed in moderate applied magnetic fields. However, electrons still play a significant role at the LaAlO₃/SrTiO₃ interface in the overall transport properties leading to electron-dominated semimetallic behavior. In an embodiment, the quantum mobility of the hole gas is greater than 10,000 cm²/Vs at 1.7K. In another embodiment, the Hall mobility of the electron gas is greater than 1,000 cm²/Vs at 1.7K.

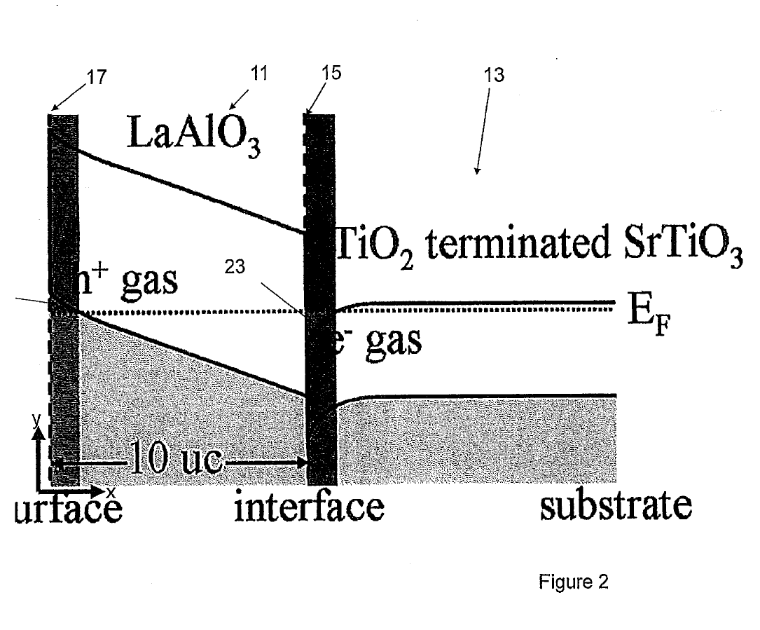

FIG. 2 shows the schematic band structure of the structure shown in FIG. 1, according to an embodiment. The band structure shows the TiO₂ terminated SrTiO₃—LaAlO₃ interface showing the surface hole gas and the electron gas at the interface. The x-axis indicates distance from the surface of the structure 17; increasing x corresponds to increasing distance from the surface 17. The y-axis indicates band energy; increasing y corresponds to increasing energy. The Fermi level E_{F} is indicated. From the band structure it is evident that the structure is a semi-metal. The valence band of SrTiO₃ curves below the Fermi level near the interface 15 such that there is electron density 23 in the valence band at the interface. Consequently, the structure comprises a two-dimensional electron gas at the interface 15. Conversely, the conduction band of LaAlO₃ curves above the Fermi level at the surface 17 of the heterostructure such that there are vacancies 21 in the conduction band at the surface. Consequently, the structure comprises a two-dimensional hole gas at the surface 17.

In an embodiment, the carrier density of the electron gas is greater than 1×10¹³ cm⁻². In another embodiment, the carrier density of the hole gas is greater than 1×10¹¹ cm⁻².

Structures according to embodiments described above comprise high mobility conducting oxide interfaces with electron behavior and surfaces with hole like behavior. Such structures can host Bose-Einstein condensed excitonic insulators and find applications in logic devices such as the CMOS (complementary metal oxide semiconductors) schemes that now dominate the electronics industry. Closely spaced electron-hole gases also provide a practical system for a superconducting state.

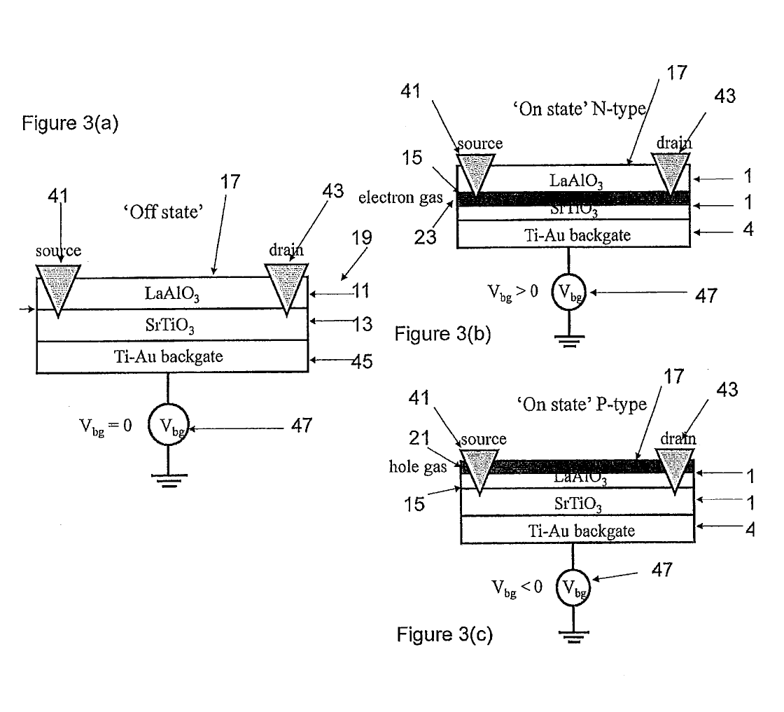

FIG. 3 shows three configurations of an electronic device according to an embodiment. The electronic device comprises the LaAlO₃/SrTiO₃ heterostructure 19 shown in FIG. 1 and described above, with layer 11 of LaAlO₃ and SrTiO₃ substrate 13 which directly interface at heterointerface 15; a source ohmic contact 41; a drain ohmic contact 43; and a backgate electrical contact 45.

The source ohmic contact 41 and drain ohmic contact 43 interface directly with both LaAlO₃ layer 11 and SrTiO₃ substrate 13. Both contacts 41, 43 are in ohmic contact with both surface 17 and interface 15. Both contacts interface directly with respective leads (not shown). The device comprises a voltage source configured to apply a voltage bias between the drain and source contacts.

The backgate electrode 45 interfaces directly with a surface of the SrTiO₃ substrate. The backgate electrode interfaces directly with a lead (not shown). The device comprises a voltage source configured to apply a voltage bias (backgate voltage) 47 between the backgate electrode and ground (backgate voltage). Examples of commercially available devices suitable for supplying the back-gate voltage are Keithley 2602 and Keithley 236 source-measure-units.

In an embodiment, the source 41, drain 43 and back gate 45 electrical contacts comprise evapourated titanium gold. In a further embodiment, the electrical contacts are unannealed. In an embodiment, the device comprises a Hall-bar patterned mesa with source and drain contacts; two contacts for resistivity and two contacts for the Hall effect.

In an embodiment, the source and drain contacts are separated by less than 1400 μm. In an embodiment, the LaAlO₃ surface layer is 3 to 10 unit cells thick. In another embodiment, the SrTiO₃ substrate 13 is 500 μm to 1 mm thick.

FIG. 3(a) shows the device according to an embodiment in an “off state” configuration. In this configuration the backgate voltage (V_{bg}=0) is zero (with respect to ground). The structure 19 is in an insulating state. Upon application of a voltage bias between source 41 and drain 43 electrical contacts, a current will not flow between them; the device is “off”.

According to one embodiment, in this configuration, structure 19 is in the excitonic insulating ground state described above. In this embodiment, structure 19 comprises neither an electron 23 nor a hole gas 21 and hence there are no mobile charge carriers in the structure.

According to another embodiment, in this configuration, structure 19 is in the electron-hole bilayer excited state (semi-metal state) described above. In this embodiment, the structure 19 comprises both an electron gas 23 at the interface 15 and a hole gas 21 at the surface 17. While there are mobile charge carriers in the structure 19, the device is configured such that at V_{bg}=0, neither the carrier density in the hole gas 21 nor the carrier density in the electron gas 23 is sufficient to enable conduction.

FIG. 3(b) shows an “on state” N-type configuration of the electronic device described above according to an embodiment. A positive voltage bias is applied to the backgate electrical contact 45 relative to ground (backgate voltage, V_{bg}).

In this configuration, the structure 19 is in the electron-hole bilayer excited state (semi-metal state) described above and comprises both hole 21 and an electron gas 23. A positive backgate voltage 47 enhances the electron density in the two-dimensional electron gas 23 and depletes the hole density in the hole gas 21 relative to their respective densities at V_{bg}=0. The electron density at the backgate voltage of the configuration shown FIG. 3(b) is sufficiently large as to enable conduction via the electron gas 13.

When a bias voltage is applied between source 41 and drain 43 electrical contacts, a current flows between the two electrical contacts via a conduction channel comprising the two dimensional electron gas 23 at the interface 15 of the structure 19. Thus, the device acts as an N-type electrical conductor.

In an embodiment, the backgate voltage of the configuration of FIG. 3(c) is sufficiently positive as to deplete the hole gas 21 such that the density of holes is insufficient for electrical conduction through the structure to occur via the hole gas 21. In another embodiment, the backgate voltage of the configuration of FIG. 3(c) is sufficiently positive as to enhance the electron gas 21 such that the electron density is sufficient to enable electrical conduction through structure 19 via the electron gas 21.

In an embodiment, the magnitude of the bias voltage required to obtain the configuration of FIG. 3(b) can be modulated by adjusting the layer thickness of the SrTiO₃ substrate 13 and/or the thickness of the LaAlO₃ surface layer. In an embodiment, the backgate voltage is larger than 10 V.

FIG. 3(c) shows an “on state” P-type configuration of the electronic device according to an embodiment. The backgate voltage V_{bg} 47 is negative.

In this configuration, the structure 19 is in the electron-hole bilayer excited state (semi-metal state) described above and comprises both a hole 21 and an electron gas 23. A negative backgate voltage enhances the hole density in the two-dimensional hole gas and depletes the electron density in the electron gas relative to their values at V_{bg}=0. The hole density at the backgate voltage of the configuration shown FIG. 3(c) is sufficiently large to enable conduction via the hole gas 21.

When a bias voltage is applied between source 41 and drain electrical 43 contacts, electrical current flows via a conduction channel comprising the two dimensional hole gas 21 at the surface 17 of the structure 19. Thus the device acts as a P-type electrical device.

In an embodiment, the backgate voltage of the configuration of FIG. 3(c) is sufficiently negative as to deplete the electron gas such that the density of electrons is insufficient for electrical conduction via the electron gas 23. In another embodiment, the backgate voltage of the configuration of FIG. 3(c) is sufficiently negative as to enhance the hole gas 21 such that the electron density is sufficient to enable electrical conduction through structure 19 via hole gas 21.

In an embodiment, the magnitude of the bias voltage required to obtain the configuration of FIG. 3(c) can be modulated by adjusting the layer thickness of the SrTiO₃ substrate 13 and/or the thickness of the LaAlO₃ surface layer 11. In an embodiment, the backgate voltage is less than 0 V.

In one embodiment, the “off state” of the device comprises the structure 19 in its excitonic insulating ground state, described above. In this embodiment, in order to switch between the “off state” and one of the “on states” described above, in addition to applying a backgate voltage bias, the device is illuminated with a red or infrared LED. In an embodiment, the illumination is carried out at temperatures of less than −243° C. In another embodiment, the device is illuminated with a red LED with a peak wavelength of 630 nm.

In another embodiment, the “off state” of the device comprises the structure 19 is in its semimetal state. In this embodiment, the device is configured such that at a backgate voltage of zero, the electron density or hole density of either electron gas 23 or hole gas 21 respectively is insufficient to enable electrical conduction through the structure. In this embodiment, switching of the device from the “off state” to one of the “on states” described above requires the application of a non-zero backgate voltage bias alone. Examples of commercially available devices suitable for supplying the back-gate voltage are Keithley 2602 and Keithley 236 source-measure-units.

The all-oxide device according the embodiment of FIG. 3 exhibits combined N and P-type conducting behaviour. Switching between the two “on states” can be achieved by modulating the backgate voltage 47.

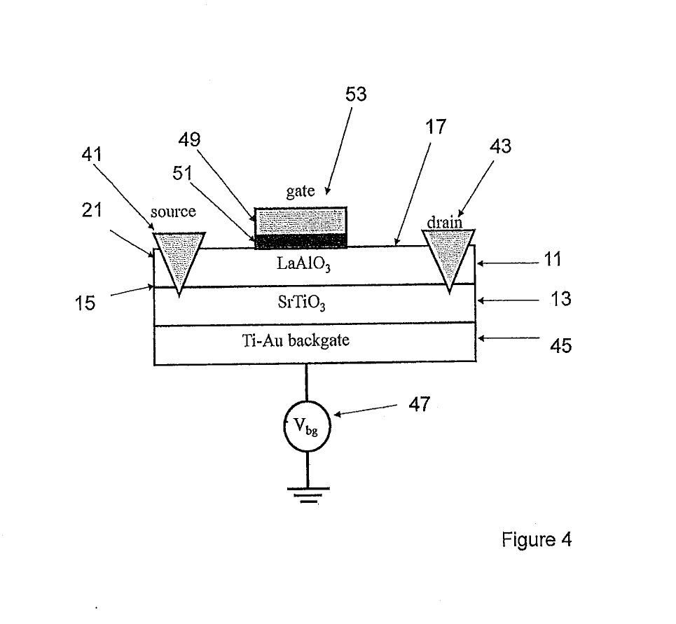

FIG. 4 shows an electronic device in accordance with another embodiment. The electronic device comprises the LaAlO₃/SrTiO₃ heterostructure 19 shown in FIG. 1 and described above, with LaAlO₃ layer 11 and SrTiO₃ substrate 13 which directly interface at heterointerface 15; a source ohmic contact 41; a drain ohmic contact 43; and a backgate electrical contact 45.

The source ohmic contact 41 and drain ohmic contact 43 interface directly with both LaAlO₃ layer 11 and SrTiO₃ substrate 13. Both contacts 41, 43 are in ohmic contact with both surface 17 and interface 15. Both contacts interface directly with respective leads (not shown). The device comprises a voltage source configured to apply a voltage bias between the drain and source contacts (not shown).

The backgate electrode 45 interfaces directly with a surface of the SrTiO₃ substrate. The backgate electrode interfaces directly with a lead (not shown). A voltage bias 47 can be applied between the backgate electrode and ground. Examples of commercially available devices suitable for supplying the back-gate voltage are Keithley 2602 and Keithley 236 source-measure-units.

In an embodiment, the source 41, drain 43 and back gate 45 electrical contacts comprise evapourated titanium gold. In a further embodiment, the electrical contacts are unannealed. In an embodiment, the device comprises a Hall-bar patterned mesa with source and drain contacts, two contacts for resistivity and two contacts for the Hall effect.

In an embodiment, the source and drain contacts are separated by less than 1400 μm. In an embodiment, the LaAlO₃ surface layer is 3 to 10 unit cells thick. In another embodiment, the SrTiO₃ substrate 13 is 500 μm to 1 mm thick.

The electronic device further comprises a front gate electrode 49. The front gate electrode 49 is insulated. The metal electrode interfaces directly with an insulator 51 which in turn interfaces directly with the surface 17 of the LaAlO₃ layer 11. A lead (not shown) interfaces directly with the front gate electrode 49. A voltage bias may be applied to the gate electrode relative to the source electrical contact (front gate voltage).

In an embodiment, the insulator 51 comprises a high-dielectric-constant material. In a further embodiment, the insulator 51 comprises MgO, Al₂O₃ or SrTiO₃. In an embodiment the gate electrode 49 comprises Ti—Au.

When structure 19 is in its semi-metallic bilayer excited state (semi-metal state), discussed above, the density of holes in the two-dimensional hole gas 21 can be modulated by adjusting the voltage applied to the front gate 53, relative to the source electrical contact (front gate voltage). When the front gate voltage is negative, the hole gas is enhanced as electrons are repelled from the surface of the structure 19. Consequently, the hole density increases and conduction via the hole gas increases. When the front gate voltage is positive, electrons are attracted to the surface of the structure. Thus, the number of holes decreases and the density of the hole gas decreases. In this case, the conductivity of the hole gas decreases.

CMOS (complementary metal-oxide semiconductor) devices employ pairs of N- and P-type field effect transistor devices to form logic gates. CMOS schemes are well known in the art and will not be discussed in detail here. The device according to the embodiment of FIG. 3 may be employed in such a scheme; the N-type “on-state” may be utilized in place of a N-type metal-oxide-semiconductor (NMOS) and the P-type “on state” may be used in place of a P-type metal-oxide-semiconductor.

Structures and devices according to the embodiments described herein have wide a band gap between valence and conduction bands. Wide band gaps are advantageous in electronic devices as they ensure that the operation of such devices is possible even at high temperatures. When small band gaps are present in a device, increased temperatures can result in thermal population of the conduction band which may alter carrier density and therefore the conduction properties of the device. Further, the band gap is direct meaning that the devices according to the embodiments described above are optically sensitive.

As MOSFET devices become increasingly small, quantum mechanical tunneling between the gate electrode and the conduction channel through the gate insulator can occur, leading to increased power consumption. High-k materials prevent leakage due to tunneling even at high gate capacitance and are therefore increasingly used in MOSFET devices as gate oxide materials. Materials with a high dielectric constant, k, enable the production of smaller devices without reduction in device reliability and gate current leakage. Compatibility with high-k materials is therefore desirable. Structures according to the embodiments described herein are compatible with materials with a high dielectric constant. Indeed, SrTiO₃ has a dielectric constant of 300 at room temperature.

The electron carrier density of the structures and devices according to the embodiments discussed above is greater than 1×10¹³ cm⁻². Higher electron carrier density correlates with decreased resistivity in the forward bias. Larger carrier densities may therefore lead to improved efficiency in electronic devices.

### Preparation

In an embodiment, the LaAlO₃/SrTiO₃ heterostructure is fabricated by expitaxial pulsed laser deposition of LaAlO₃ on single crystal, TiO₂ terminated SrTiO₃ substrates. An example of a laser suitable for use in pulsed laser deposition is a KrF excimer laser operating at 248 nm and a laser fluence of ˜1 J/cm².

In an embodiment, the StTiO₃ substrate is 500 μm to 1 mm thick. In a further embodiment, single atomic layers of (single crystal) LaAlO₃ are deposited at temperatures of at least 800° C. under oxygen at a pressure of at least 10⁻³ mbar. In yet a further embodiment, the layer of deposited LaAlO₃ is 3 to 10 unit cells thick.

In an embodiment, the structure is annealed by exposing it to oxygen pressure of at least 0.1 mbar at a temperature of at least 800° C. and cooling to ambient temperatures under the same oxygen pressure. In an embodiment, the structure is then illuminated using a red or infrared light emitting diode. An example of an LED suitable for use in illumination of the structure is a red LED providing 630 nm wavelength illumination. In an embodiment, the illumination is carried out at a temperature of less than −243° C.

In an embodiment, an electronic device is fabricated from the LaAlO₃/SrTiO₃ heterostructure prepared as described above. In an embodiment, Hall-bar shaped mesas are formed using optical photolithography and Ar ion beam etching to remove the unwanted LaAlO₃ from the mesa. In a further embodiment, a back gate is thermally evaporated onto the back of the SrTiO₃ substrate. In an embodiment, the back gate comprises titanium gold. In an embodiment, ohmic source and drain contacts are thermally evapourated onto the device. In an embodiment, the source and drain contacts comprise titanium gold. In an embodiment they are not annealed. In an embodiment source and drain contacts fabricated such that they are separated by less than 1400 μM and the channel width is less than 80 μm. In an embodiment, they are fabricated such that they are in ohmic contact with both electron gas and hole gas.

In an embodiment, a front gate electrode consisting of Ti—Au is formed on the surface of the LaAlO₃ surface layer.

In an embodiment, voltage probes are fabricated from Ti—Au with thickness 20 nm of Ti and 100 nm of Au.

### Experimental Results

Three devices A, B and C according to an embodiment of the present invention were prepared by pulsed laser deposition of LaAlO₃ on single crystal, TiO₂ terminated SrTiO₃ substrates. Single atomic layers of (single crystal) LaAlO₃ were deposited at 800° C. under oxygen at 10⁻³ mbar. A KrF excimer laser (at 248 nm) was used for the ablation of the LaAlO₃ target material at a laser fluence of ˜1 J/cm².

After growth the samples were exposed to a high oxygen pressure (˜0.1 mbar) for in-situ annealing at 800° C. for 15 minutes. It was then cooled to ambient temperature at the same oxygen pressure.

A, B and C were formed from a single growth of 10 unit cells of LaAlO₃. Hall bar shaped mesas were formed using optical photolithography and Ar ion-beam etching. A titanium gold (Ti—Au) back gate was thermally evaporated on the back of the 500 μm thick SrTiO₃ substrate so that a substrate bias (V_{bg}) could be applied to the device. The SrTiO₃ substrate remained insulating after all levels of processing. The source and drain ohmic contacts were fabricated with thermally evaporated but unannealed Ti—Au. These contacts are suitable as both electron and hole gas contacts.

No leakage current (from −30 to +50 V_{bg}) was observed between the back gate contact and the source-drain contacts. The channel width was 80 μm, the voltage probes had length-to-width ratios of 4.2 and the source and drain contacts were separated by 1400 μm.

Hall bar devices were measured with a source-drain current of 100 nA at 33 Hz. The gate voltage was supplied either from a Keithley 2602 or Keithley 236 source-measure-unit through a low pass filter. A magnetic field could be applied from −8 to 8 T with a variable temperature range from 300 K to 1.7 K. The temperature was measured with a calibrated cernox sensor close to the device. An in-situ LED provided red (630 nm) wavelength illumination. The ac voltages corresponding to Rₓₓ and R_{xy} were pre-amplified then measured with Stanford SR830 lockin amplifiers.

The samples were insulating in the dark at low temperature. This is due to the 10⁻³ mbar partial pressure of O₂ during growth combined with the high pressure anneal. The three devices were illuminated in-situ by a red LED (630 nm peak wavelength) at the base temperature of 1.7K.

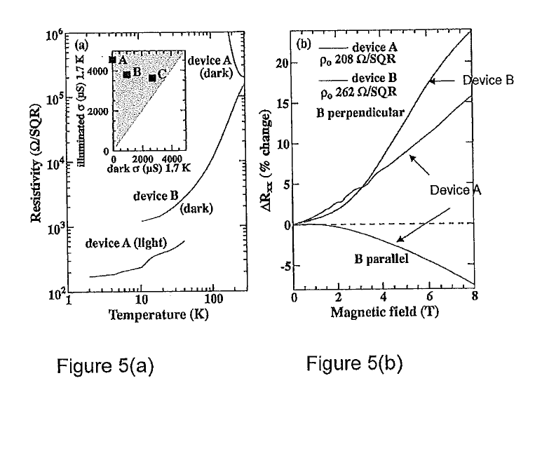

FIG. 5(a) shows the persistent conductivity effect in the three electronic devices A, B and C. In the main figure, resistivity is plotted as a function of temperature. Results are shown for device A before (labelled “dark”) and after (labelled “light”) illumination and for device B before illumination.

The low resistance state after illumination is stable until the temperature is increased above ˜40 K. However, minor abrupt changes in device A do occur (˜10K) in device A on warming as can be seen in FIG. 5(a). Initially the resistance of device A goes beyond the measurement range as the temperature is lowered, but via a PPC effect the sample becomes semimetallic at 1.7 K having a similar conductance values to other devices from the same wafer. In the case of device A the PPC effect remains stable over a relatively long period (dρₒ/dt<+1.5 10⁻⁴Ω/□ per second) of measurement time (t˜10⁴ s) at 1.7 K. Device B follows a similar resistivity (ρₒ) trend ρₒ˜T² (for temperature T>77 K) to Fermi liquid behaviour of an electron gas. Fermi liquid behaviour is well known in the art and will not be discussed here.

In the inset to FIG. 5(a), conductivity σ after illumination (y-axis) is plotted against the conductivity a before illumination (x-axis) for all three devices A, B and C at 1.7K, i.e. the before and after illumination conductivities for the three nominally identical devices. In all cases the conductivity increases (indicated by the shaded area) persistently to ˜4000 μS after illumination at 1.7 K. The persistent photoconductivity (PPC) effect is stronger in devices that are insulating in the dark at 1.7 K. Devices fabricated in the same growth chamber with a low oxygen pressure growth (10⁻⁶ mbar) show no PPC effect.

FIG. 5(b) shows the magnetoresistance in a perpendicular magnetic field at 1.7 K for devices A and B. The change in magnetoresistance ΔRₓₓ is plotted as a function of magnetic field, B. The zero field resistivities (ρₒ) are indicated for the two devices; ρ₀=208Ω/SQR for device A and ρ₀=208Ω/SQR for device B. The magnetoresistance for device B is plotted for a perpendicular field and the magnetoresistance for device A is indicated for both perpendicular and parallel fields (the parallel field giving rise to negative ΔRₓₓ).

Magnetoresistance (MR) measurements were made up to 8 T with an ac current of 100 nA at 33 Hz. Oscillatory structure is present in the magnetoresistance (Rₓₓ) of device A from the surface hole gas in a perpendicular magnetic field (B), i.e. along the [001] direction of SrTiO₃. The oscillation is superimposed on a positive magnetoresistance due to electron and hole multiband conduction contributing to a large classical background resistivity. These oscillations are due to the Shubnikov-de Haas effect on the hole gas at the surface of the LaAlO₃ layer. The Shubnikov-de Haas effect is well known in the art and will not be discussed in detail here. The oscillatory structure in device A disappears with a negative background MR when the field is applied in-plane (i.e. parallel). This is known from the art to be consistent with two-dimensional behaviour. Device B shows a similar positive magnetoresistance in a perpendicular field without an oscillatory structure superimposed on it.

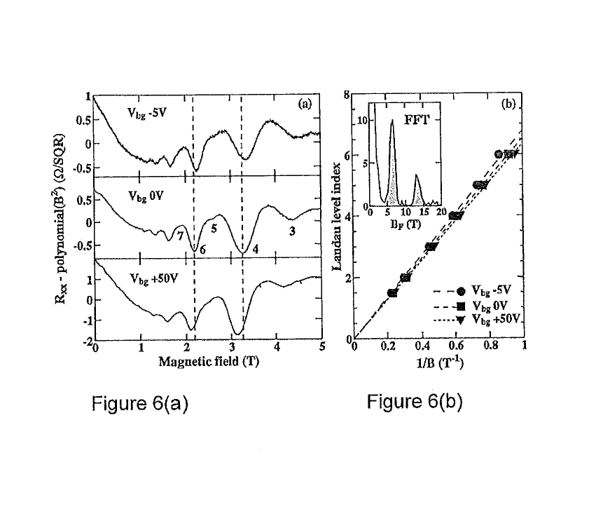

FIG. 6a shows the magnetoresistance Rₓₓ for device A, with a parabolic background subtracted to enhance oscillatory structure due to the Shubnikov-de Haas effect, plotted as a function of magnetic field, for three values of the backgate voltage V_{bg}: V_{bg}=−5, 0 and +50 at 1.7K. The dotted lines show the minima at υ=4 and 6 for V_{bg}=0 V. Other filling factors are labeled. A spin-splitting is apparent at odd filling factors 3, 5 and 7. Shubnikov-deHaas oscillations from the hole gas can be clearly seen down to a Landau level filling factor (υ) of 12 and are periodic in 1/B. The oscillations start at B˜1 T, corresponding to a quantum mobility (μ_{q}) of 10,000 cm²/Vs.

FIG. 6(b) shows a fit of Landau level harmonic index against 1/B for the Shubnikov-de Haas minima at three different back gate voltages V_{bg}=−5V, 0 V and +50V. A Fast Fourier Transform (FFT) of the oscillatory structure due to the hole gas in 1/B is shown in the inset for the case of V_{bg}=0 V. Fast Fourier Transform of Shubnikov-deHaas oscillations is a standard technique for determining fundamental fields, multiple subband effects including spin and the actual carrier densities. The quantum mobility (μ_{q}) of the carriers involved can also be determined from the FFT. If the ½ width at ½ height of the peak in the FFT is δB, then:

$${μ}_{q} = \frac{\sqrt{3}}{2} \cdot \frac{1}{δ B}$$

providing that the Shubnikov-deHaas oscillations in ρₓₓ for a band (electron or hole) with a carrier density of nₛ can be described by:

$${ρ}_{xx} ( B ) ∝ {e}^{- \frac{π}{{μ}_{q} B}} \cdot cos ( \frac{{hn}_{s}}{2 eB} ) .$$

Another common method is to apply a FFT to dρₓₓ/dB, in which case

$${μ}_{q} = \frac{( {4}^{1 / 3} - 1 )}{2} \cdot \frac{1}{δ B} .$$

The second harmonic in the FFT is due to spin-splitting at υ=3, 5 and 7 being included in the field domain of the FFT. The results show that the hole gas has no Berry phase and the oscillations are strictly 1/B periodic. The fundamental field (B_{F}) is 6.5 T with a harmonic peak at 13 T. This harmonic peak is a mathematical artifact arising from including spin-splitting in the magnetic field domain for the FFT, rather than being a second hole subband or due to a higher density electron gas. The ½ width at ½ height of the FFT power spectrum peak (SB) is 0.9±0.1 T corresponding to a quantum mobility μ_{q}˜13500±1500 cm²/V·s. There is a systematic shift of the oscillatory structure depending on carrier accumulation or depletion, confirming the hole-like behaviour of these oscillations in response to a back gate field.

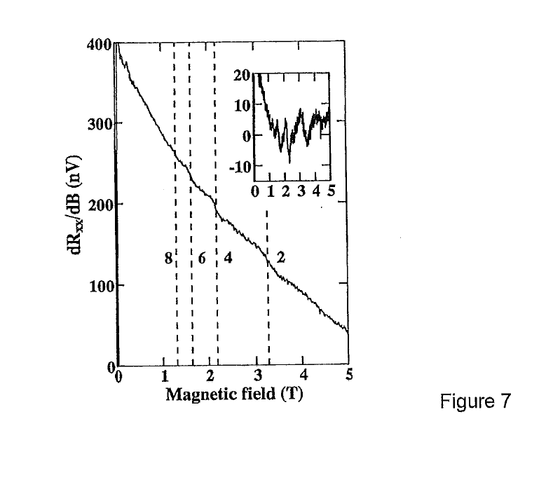

FIG. 7 shows the analogue signal dRₓₓ/dB in device A for V_{bg}=0 V at 1.7 K up to 5 T. The dotted lines show the Shubnikov deHaas minima positions (labeled by filling factor) expected for a hole carrier density of 3 10¹¹ cm⁻². The inset shows the same data set with a polynomial to order B² subtracted from dRₓₓ/dB. The units on the axes for the inset are the same as the main graph. This technique is an alternative method of measuring oscillatory magnetoresistance behavior. A dc current (˜100 nA) is applied to the source-drain contacts and a small ac magnetic field (typically up to 10 mT) is applied to the device on top of the steady magnetic field. Analogue dRₓₓ/dB measurements for device A in a modulated magnetic field (5.6 mT at 33 Hz in this case) show a weak Shubnikov-deHaas effect signal due to the large background signal (originating from Rₓₓ˜B²). The same oscillatory structure as observed in FIG. 6a can be seen, albeit in dRₓₓ/dB which has a phase change in the oscillations of π/2 compared to Rₓₓ.

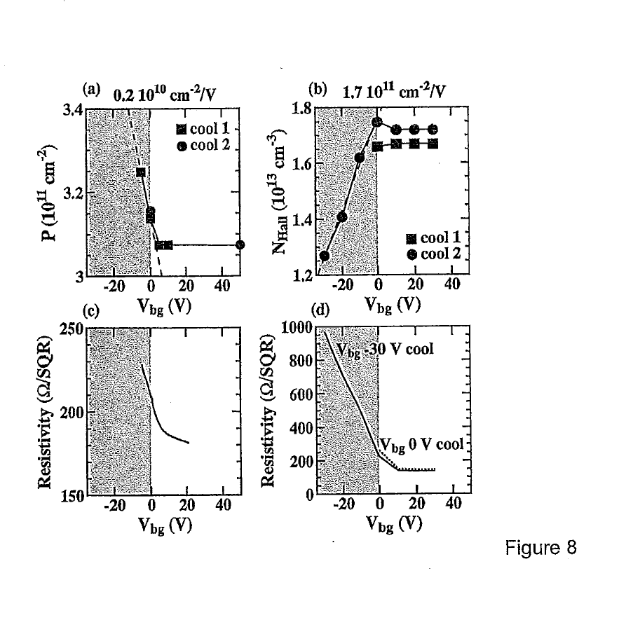

FIG. 8 (a) shows the change in hole density (P) with gate bias V_{bg} in device A at 1.7K. The hole density is enhanced with a negative gate field. Two different cool-downs (300 K to 1.7 K) are shown. Assuming that the valence band Fermi surface formed from O 2p states is circular then the hole density (P) can be calculated from:

$$P = {g}_{v} {g}_{s} \frac{{eB}_{F}}{h}$$

where gᵥ is the valley degeneracy and gₛ is the spin degeneracy. B_{F} is the fundamental field of the Shubnikov-deHaas oscillations where the Landau level harmonic index is 1. The valence band valley degeneracy is assumed to be 1, however this assumption does not change the interpretation that a hole gas with density ˜10¹¹ cm⁻² is present in the structure.

Note that the hole-like Shubnikov-deHaas effect is not due to a hole-like electron orbit on the SrTiO₃ Fermi surface at the interface that shrinks in extremal area with increasing the Fermi k vector (for example with positive gate field or illumination). This would require either an indirect band structure in SrTiO₃ or an artificially periodic structure on the length scale of the (LaO)⁻—(AlO₂)⁺ perovskite planes.

FIG. 8 (b) shows the change in electron density N_{Hall} with gate bias V_{bg} in device B at 1.7 K. Again, two different cool-downs (300 K to 1.7 K) are shown. In this case, cool-down 1 is at V_{bg}=0 V and cool-down 2 is for V_{bg}=−30 V (bias cool-down). The electron gas is depleted with a negative gate field. With the electron gas in enhancement mode an initial decrease in the carrier density is observed for the case of a bias cool down (cool-down 2 with −30 V_{bg}) designed to enhance any hole gas. Cool-down 1 (no bias on cooling; no hole-enhancement) does not show this effect. The capacitance of the electron gas is 1.7 10¹¹ cm⁻²/V and the capacitance of the hole gas is 0.2 10¹⁰ cm⁻²/V. This difference is due to efficient screening of the backgate field by the electron gas at the LaAlO₃/SrTiO₃ interface and confirms the spatial separation of the two charge systems, as shown in FIG. 2. A strong hysteretic behavior is observed in Rₓₓ when changing the voltage on the backgate and this is partly explained by the ferroelectric response of the SrTiO₃ substrate. All the devices tend to insulating behavior for strong electron depletion (−V_{bg}) but can be ‘reset’ at low temperatures via the PPC effect at V_{bg}=0 V.

FIGS. 8 (c) and (d) show are the corresponding changes in resistivity with backgate voltage V_{bg} for device A and B respectively. Both are dominated by the electron density and resistivity decreases as electron density increases (see FIG. 8(b)).

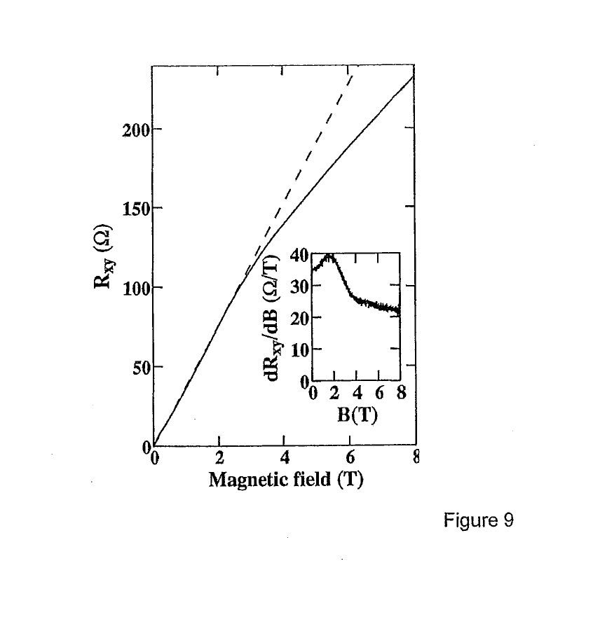

FIG. 9 shows the Hall resistance R_{xy} of device B as a function of magnetic field 1.7 K up to 8 T at V_{g}=+10 V. The dotted line shows the expected behaviour for a single carrier type with a density of 1.7 10¹¹ cm⁻². The inset shows the Hall constant (dR_{xy}/dB) with noise (±2.5% of the signal at 8 T) due to digital differentiation. Device B has a non-linear Hall resistance with magnetic field. The Hall resistance is magnetic field anti-symmetric, i.e. R_{xy}(−B)=−R_{xy}(B), however occasional devices show a finite Hall voltage at zero field due to contact mis-alignment effects.

R_{xy} at zero field in device B is <1.4Ω, this corresponds to a measured voltage of <0.14 μV for 100 nA current. The non-linear Hall resistance (not due to mixing of the Rₓₓ component) is due to a parallel conduction effect due to the electron and hole gas that are connected in parallel via the Ti—Au Ohmic contacts.

The hole density cannot be uniquely determined from the Hall effect due to the dominance of the parallel conducting electron gas. From FIGS. 8(c) and (d), devices A and B show an electron gas depleting with a negative gate field. The Hall resistance (R_{xy}) shows a linear behavior in magnetic field (up to ˜2 T) and the electron density (N) can be determined from dR_{xy}/dB, see FIG. 8b. The non-linear Hall slope seen above 2 T in device B (FIG. 9) confirms the multiple carrier conduction effects, albeit electron dominated. The electron density is 1.7 10¹³ cm⁻² in device B with a corresponding Hall electron mobility of 1500 cm²/V·s. This mobility is known from the art to be consistent with n-type conduction albeit with slightly higher mobility here.

At the high O₂ pressure (10⁻³ mbar) used during the growth of these devices the electron gas is confined at or close to the LaAlO₃/SrTiO₃ interface and the structure is low in oxygen vacancies that would provide a source of n-type dopant. The electron gas is isolated from the unoccupied valence states at the surface through an insulating LaAlO₃ layer without the influence of a high oxygen vacancy background. This combination of effects with such a clean system observed here is expected to be semimetallic from the polar catastrophe mechanism, with the Ti 3d-like conduction band at the interface and the O 2p valence band partially full of electron states at the surface, as shown in FIG. 2. The polar catastrophe mechanism is well known in the art and will not be discussed here. The clean system reduces the tunneling or more likely hopping of electrons from the interface into the O 2p valence band at the surface. The PPC effect with below band gap photons enhances both the electron gas and the hole gas and is partly an extrinsic charge effect in origin where the thermal barrier (kT) is 3.5 meV.

The hole mobility in principle should be lower than the electron gas reported at n-type interfaces, however the electron gas can screen potential fluctuations at the LaAlO₃/SrTiO₃ interface partly accounting for a high hole mobility. The Shubnikov-deHaas effect shows a spin-splitting at odd Landau level filling factors and points to the importance of spin in understanding the structure of the O 2p valence band.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semi-metallic structure, comprising
an LaAlO₃—SrTiO₃ heterostructure (19),
said LaAlO₃—SrTiO₃ heterostructure comprising a two-dimensional hole gas (21) and a two-dimensional electron gas (23).

2. The semi-metallic structure according to claim 1,
wherein said structure exhibits persistent photoconductivity following illumination with a red or infrared illumination source at temperatures below −243° C.

3. The semi-metallic structure according to claim 2,
wherein said red or infrared illumination source is a red light emitting diode with a peak wavelength of 630 nm.

4. The semi-metallic structure according to claim 1,
wherein said LaAlO₃—SrTiO₃ heterostructure (19) comprises an SrTiO₃ substrate (13) and an LaAlO₃ surface layer (11).

5. The semi-metallic structure according to claim 4,
wherein said SrTiO₃ substrate (13) and said LaAlO₃ surface layer (11) have perovskite structures.

6. The semi-metallic structure according to claim 4,
wherein said hole gas (21) is located on a surface (17) of said LaAlO₃ surface layer (11) and said electron gas (23) is located at the LaAlO₃/SrTiO₃ interface (15).

7. The semi-metallic structure according to claim 6,
wherein said LaAlO₃ surface layer (11) is between 3 and 10 unit cells thick inclusive.

8. The semi-metallic structure according to claim 6, wherein said surface (17) of said LaAlO₃ surface layer (11) is terminated by AlO₂⁻.

9. An electronic device comprising the semi-metallic structure according to claim 4 and
a first back-gate electrode (45) on a surface of said SrTiO₃ substrate (13);
a first source electrical contact (41);
a first drain electrical contact (43); and
a red or infrared illumination source.

10. The electronic device of claim 9 wherein said first source electrical contact (41) and first drain electrical contact (43) are configured such that they make ohmic contact with both said two-dimensional hole gas (21) and said two-dimension electron gas (23).

11. The electronic device of claim 9 further comprising:
a front-gate electrode (53) on a surface (17) of said LaAlO₃ surface layer (11).

12. The electronic device of claim 11 wherein said front-gate electrode (53) comprises MgO, Al₂O₃ or SrTiO₃.

13. The electronic device of claim 9, further comprising a voltage source configured to apply a bias voltage between said first source electrical contact (41) and said back-gate electrode (45).

14. The electronic device of claim 9,
wherein the hole density of said two-dimensional hole gas (21) increases and the electron density of said two-dimension electron gas (23) decreases upon application of a negative bias voltage between said first source electrical contact (41) and said back-gate electrode (45).

15. A method of operating the electronic device of claim 9 comprising
cooling the device to a temperature below −243° C.;
illuminating the device with said red or infrared illumination source; and
applying a bias voltage between said first source electrical contact (41) and said first drain electrical contact (43).

16. A fabrication method for fabricating a semi-metallic structure, wherein said semi-metallic structure comprises an LaAlO₃—SrTiO₃ heterostructure (19) comprising a two-dimensional hole gas (21) and a two-dimensional electron gas (23),
said method comprising:
depositing LaAlO₃ on a TiO₂ terminated SrTiO₃ substrate (13),
wherein said depositing is performed under an oxygen pressure of at least 10⁻³ mbar and at a temperature of at least 800° C.;
heating said structure to a temperature of at least 800° C., and
cooling said structure to ambient temperature,
wherein said heating and cooling of said structure are performed while exposing said structure to an oxygen pressure of greater than 0.1 mbar; and
illuminating said structure using a red or infrared illumination source at temperatures less than −243° C.

17. The fabrication method of claim 16,
wherein said illuminating of said structure is performed using a red light emitting diode with a peak wavelength of 630 nm.

18. The fabrication method of claim 16, further comprising:
forming a back-gate electrode (45) on a first surface of said heterostructure (19);
forming a source electrical contact (41) such that said source electrical contact (41) is in ohmic contact with both said two-dimensional hole gas (21) and said two-dimensional electron gas (23); and
forming a drain electrical contact (43) such that said drain electrical contact (43) is in ohmic contact with both said two-dimensional hole gas (21) and said two-dimensional electron gas (23).

19. The fabrication method of claim 16, further comprising
forming a front-gate electrode (53) on a second surface (17) of said heterostructure (19).

20. The fabrication method of claim 16 wherein said depositing of LaAlO₃ comprises depositing single atomic layers of LaAlO₃.
